(19) United States
(12) Patent Application Publication
(10) Pub. No.: US 2022/0344527 A1
(43) Pub. Date: Oct. 27, 2022

(54) ADHESIVELY BONDED, DECORATIVE SOLAR PANEL AND METHOD OF MANUFACTURE THEREOF

(71) Applicant: APTERA MOTORS CORP., San Diego, CA (US)

(72) Inventor: Anuj M. THAKKAR, San Diego, CA (US)

(73) Assignee: APTERA MOTORS CORP., San Diego, CA (US)

(21) Appl. No.: 17/829,124

(22) Filed: May 31, 2022

Related U.S. Application Data
(63) Continuation-in-part of application No. 17/035,244, filed on Sep. 28, 2020.
Application No. 17/035,244 is a continuation-in-part of application No. 17/063,529, filed on Oct. 5, 2020, now abandoned.

(51) Int. Cl. H01L 31/049; B60R 11/00

(52) U.S. Cl. CPC H01L 31/049; B60R 11/00; B60R 2011/0005; B60R 2011/0063

(57) ABSTRACT

An adhesively bonded dashboard including a solar module, and methods of manufacture pertaining thereto, are provided. The dashboard may be decorative in terms of an aesthetically pleasing texture and/or color. The solar cells contained therein may be curved along one axis of curvature to form one or more desirable shapes.

### RELATED APPLICATIONS

This application is a continuation-in-part of U.S. patent application Ser. No. 17/063,529 filed Oct. 5, 2020, which is incorporated herein by reference in its entirety.

### TECHNICAL FIELD

The present disclosure relates generally to flexible solar modules integrated with a molded panel. In particular, the present disclosure relates to an apparatus, system, and method for a vehicle dashboard having an adhesively bonded, decorative solar panel that may be flat or have one axes of curvature.

### BACKGROUND

Recently the demand for mobile solar panels and non-flat geometry solar panels has sparked innovations for both polymer- and glass-based panels. Such applications value light weight, durability and low cost. However, other considerations, such as appearance and surface texture, have become important in consumer applications. Some of the most challenging requirements come from the electric vehicle industry where solar-enabled body panels have been a topic of intense research and development for three decades. Vehicle body panels typically have complex shapes and harsh environment operability and durability requirements. However, solar panels having complex geometries are challenging to manufacture for a variety of reasons, the most obvious of which is damage to or destruction of the delicate solar cells. In applications where solar modules are integrated with components that are expected to receive human contact, the look and feel of such components have a bearing on their marketability. The current disclosure addresses this need in any molded panel application, and, by way of example, this disclosure uses an embodiment of an automotive dashboard application to discuss specific enabling features yet is not specifically limited thereto as a solar panel having complex shapes has applications in architectural, marine, aeronautical, space, and other useful applications.

Conventional solar panels have been applied to or integrated with dashboards using one of two methods. In a first method, a thin, flexible solar panel, either incorporated into a flexible dashboard cover or as a flexible stand-alone solar panel of the type commercially available, as for example, from Renogy LLC Ontario, Calif., is either placed or adhered to the surface of a molded dashboard as an aftermarket installation. In this case, the solar module and cells are either flat or curved in a single dimension.

In a second method, a solar panel is integrated with the dashboard via injection molding. For injection molding, the solar module or individual cells remain flat while the outer facing surface of the dashboard panel may be curved. To retain a flat form, the solar module may be restricted to a flat portion of the dashboard surface, or it may be disposed on a flat subsurface, such as the back surface. Alternatively, it may be disposed on a flat intermediate surface, or an array of such surfaces, that is/are enclosed between top and bottom portions of the dashboard. In the injection molding approach, the preferred method is a backside molding followed by a frontside molding, which provides the advantage of encapsulating the cells or module in the injected polymer thereby sealing the edge. A frontside only approach is also possible. However, a back sheet or other sealing arrangement is required to protect the module against moisture. Also, backside only injection molding may be possible. However, the need to retain the solar module during the injection process, typically in a recess, diminishes the ability to seal the panel edge due to interference from the retaining feature, such as said recess. As a further consequence, the module can no longer present a flush interface with the rest of the dashboard.

In both methods, neither the surface finish nor the color of the resulting panels is specified. It is important in most consumer applications, however, that the surface texture and color be controlled for visual and tactile purposes. For example, in a dashboard application it is important that the reflection of the dashboard in the windshield be minimized for driver safety. In another example, it is desirable that the solar cells blend in with their surroundings or are otherwise obscured from view. Finally, it is important that the surface of the dashboard conform somewhat to the accepted norms of the automobile industry, such as having a seamless, curved and textured surface, in order to ensure consumer acceptance.

What is needed is a decorative, flexible solar-enabled panel and method of fabricating configured to include color and texture and/or with a seamless, robust, textured surface that can minimize withstand intense solar radiation and repeated human contact over the life of the panel. Other desirable features and characteristics will become apparent from the subsequent detailed description, the drawings, and the appended claims, when considered in view of this background.

### SUMMARY

It is an object of the present disclosure to provide an apparatus, system and method for a solar dashboard panel that has a seamless, robust, textured surface that can withstand intense solar radiation and repeated human contact over the life of the vehicle.

It is an object of the present disclosure to provide a solar panel that is compatible with automotive applications.

It is an object of the present disclosure to provide a solar panel that may be mass produced at low cost.

It is an object of the present disclosure to provide a system and method for producing a solar panel with the above properties.

### DESCRIPTION OF THE DRAWINGS

Non-limiting and non-exhaustive embodiments of the present disclosure are described with reference to the following drawings. In the drawings, like numerals describe like components throughout the several views.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective view of a curved dashboard assembly including an integrated flexible solar module, wherein the solar module is shown without surface texture for clarity, according to an embodiment of the present invention;

FIG. 1B illustrates a perspective view of a curved dashboard assembly including an integrated flexible solar module, wherein the solar module is shown with surface texture, according to an embodiment of the present invention;

FIG. 2 illustrates a cross-sectional view of FIG. 1B showing a curved dashboard assembly having an integrated flexible solar module, according to an embodiment of the present invention;

FIG. 3A illustrates an exploded, perspective view of solar module layers arranged in a stack, according to an embodiment of the present invention;

FIG. 3B illustrates a perspective view of a flexible solar module that has been laminated as a flat sheet, according to an embodiment of the present invention;

FIG. 3C illustrates a perspective view of a flexible solar module that has been laminated as a flat sheet and has a textured surface, according to an embodiment of the present invention;

FIG. 4 illustrates an exploded, perspective view of a curved dashboard assembly including an integrated flexible solar module, wherein the molded panel includes a groove, according to an alternative embodiment of the present invention;

FIG. 5 illustrates a texture imparted to a frontsheet of an integrated flexible solar module, according to an embodiment of the present invention;

FIG. 6A illustrates a perspective view of a curved dashboard assembly including an integrated flexible solar module, wherein the cap layer is shown without surface texture for clarity, according to an alternative embodiment of the present invention;

FIG. 6B illustrates a perspective view of a curved dashboard assembly including an integrated flexible solar module, wherein the cap layer is shown with surface texture, according to an alternative embodiment of the present invention;

FIG. 7 illustrates a cross-sectional view of FIG. 6B showing a curved dashboard assembly having an integrated flexible solar module, according to an alternative embodiment of the present invention;

FIG. 8 illustrates an exploded perspective view of a curved dashboard assembly including an integrated flexible solar module, wherein the molded panel includes a recess, according to an alternative embodiment of the present invention;

FIG. 9 illustrates a perspective view of a curved dashboard assembly including an integrated flexible solar module, wherein the molded cap is shown with a latching feature, according to an alternative embodiment of the present invention;

FIG. 10 illustrates an exploded perspective view of a curved dashboard assembly including an integrated flexible solar module, wherein the molded cap and panel include latching features, according to an alternative embodiment of the present invention; and

FIG. 11 illustrates a cross-sectional view of FIG. 9 showing a curved dashboard assembly having an integrated flexible solar module, wherein the molded cap and panel include latching features, according to an alternative embodiment of the present invention.

### DETAILED DESCRIPTION

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are provided for the purposes of illustrating some embodiments of the present disclosure, and are not to be considered as a limitation thereto. The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

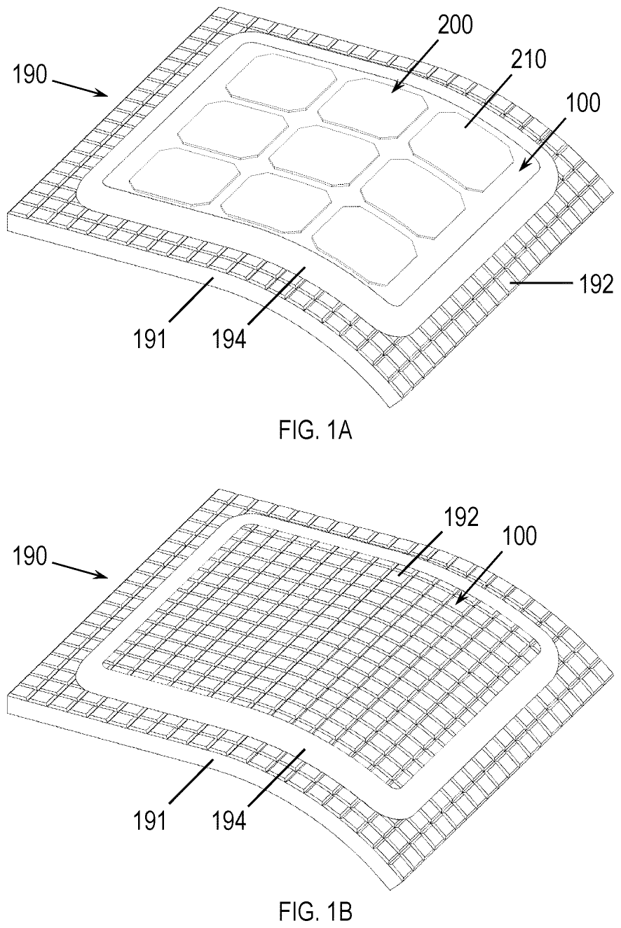

The drawings, including FIGS. 1A-1B through 11, may contain sizes and shapes of respective portions that are appropriately exaggerated for ease of understanding. Therefore, the comparative sizes and/or shapes displayed in the drawings should be considered non-limiting.

In a first embodiment, illustrated in FIGS. 1A and 1B, a dashboard assembly 190 comprises an integrated flexible solar module 100 that includes a textured surface 192 coupled to a molded panel 191. In this context, the term “integrate” or “integrated” or means that the solar panel is combined with the dashboard in such a way that it cannot be removed without significant effort and/or damaging the assembly. The term “integrate” or “integrated” may further, or alternatively, refer to a solar module and/or dashboard installed by the original equipment manufacturer (OEM), which may not be easily removed other than for repair or replacement.

In FIG. 1A the solar module 100 may be flat or have simple curvature, that is, curved in one direction, such that the individual cells 210 may also be flat or curved in one direction. In contrast, the dashboard panel 191 may have simple or complex curvature. The solar module 100, shown without surface texture for clarity, comprises a solar cell array 200 further comprised of individual solar cells 210 and interconnects (not shown). Solar cells 210 may be of the semi-flexible, interdigitated, back-contact cell type, available from multiple vendors, such as SunPower which produces the Maxeon® Gen III (3) flexible solar cell. However, other types of solar cells, such as heterojunction, thin film, perovskite, etc. may also be used and the previous example is offered without limitation. Solar cells 210, as shown in FIG. 1A, may be arranged with the short axis oriented substantially parallel to the longitudinal axis of the vehicle, such that the short axis of the cell may be curved. Alternatively, solar cells 210 may be arranged with the long axis of the cell, i.e., the diagonal axis, oriented substantially parallel to the longitudinal axis of the vehicle, such that the long axis of the cell may be curved. The array 200 is surrounded by encapsulant layers and protective sheets.

Referring to FIG. 1B, a top layer of the solar module may be textured 192 to provide a pleasing tactile perception, to reduce reflection of available light intended for the solar cells, and/or to provide a decorative appearance. A bottom layer or interface below the solar cells 210 may be colored or printed to provide an aesthetic appearance and/or to cause the cell array 200 to blend into the dashboard, that is, having substantially no contrast with it. The edge of the solar module is secured and protected by a gasket or border 194 which snaps into or is otherwise coupled to the dashboard panel 191. The border may also be textured so as to provide a more uniform texture over the assembly surface.

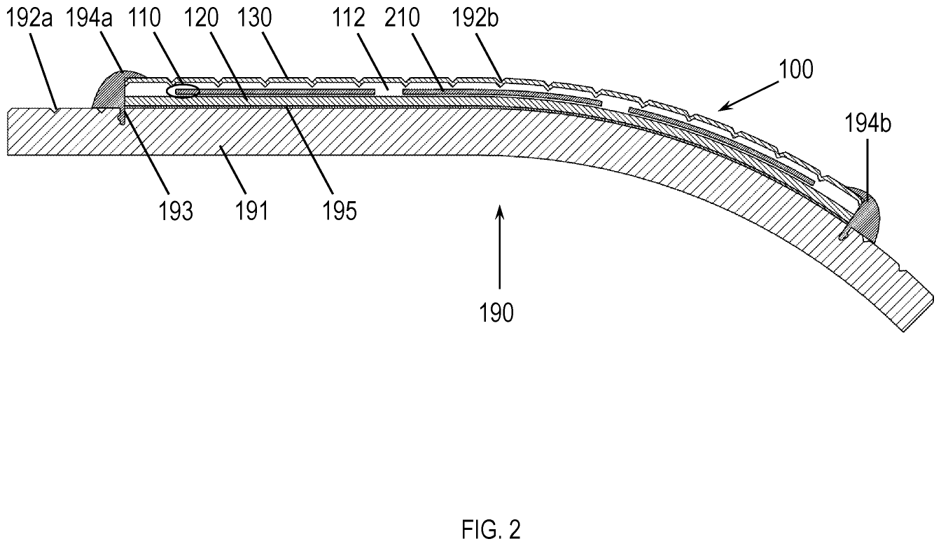

Referring to FIG. 2, the dashboard assembly 190 comprises a molded panel 191 with both textured 192a and non-textured portions separated by a groove 193 or other latching feature. The solar module 100 is disposed on the non-textured portion of the panel and coupled thereto by an adhesive layer 195. Adhesive layer 195 may comprise an acrylic-based adhesive transfer tape, sheet or other suitable product such as, for example, clear 3M Adhesive Transfer Tapes, e.g. Product No. 3M 9471 LE, commercially available and manufactured by 3M Corporation (See, e.g., https://www.3m.com/3M/en US/p/d/b40071696/). Alternatively adhesive layer 195 may comprise a silicone material, an epoxy, or other type of glue. A gasket or border 194a, 194b may be disposed around the perimeter of the panel 100 and secured to the dashboard panel 191 via the groove 193. The groove 193 and gasket 194 may have latching features and/or may be secured by fasteners or an adhesive joint.

The flexible solar module 100 comprises a core 110, a backsheet 120 and a frontsheet 130. The solar cells 210 within the core 110 may be flat or curved in one direction. The thicknesses of the layers are chosen such that the panel 100 remains flexible after lamination. The backsheet 120 comprises a thin layer of a durable polymer, such tedlar polyester tedlar (TPT) or ethylene tetrafluoroethylene (ETFE). The backsheet 120 may be colored by means of dyeing of the extrudate, post-extrusion dyeing, or by spraying or printing of paint or ink on one or both surfaces. The core 110 comprises a solar cells 210 encapsulated in a flowable polymer, such as polyolefin elastomers (POE) or ethylene vinyl acetate (EVA). The frontsheet 130 is disposed on the top of the laminate stack and comprises a durable polymer capable of short-range deformation (<1 mm) imparted by low force tooling, such as the film form of ETFE or polycarbonate (PC). It may be appreciated by one skilled in the art that other choices of material for the various layers may be made and the specific examples mentioned here are therefore non-limiting. The frontsheet 130 may have a texture surface 192b that matches the textured surface 192a of the molded dashboard panel 191.

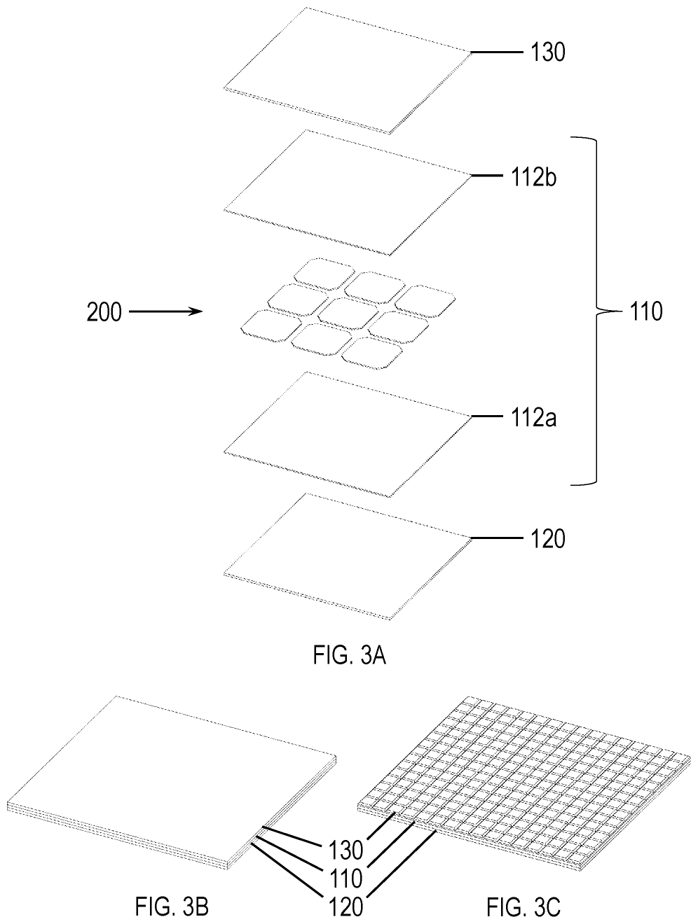

A method of manufacturing is provided, as illustrated in FIGS. 3A, 3C, 4 and 5. In a first step, shown schematically in FIG. 3A, the solar panel layers are arranged in a stack. The stack represents the order of the layers and may be implemented as sheets, as in a flat lamination process, or as rolls, as in a roll-to-roll lamination process. The backsheet 120 is disposed at the bottom, followed by the core 110 comprising a bottom encapsulant 112a, the solar cells 210, and a top encapsulant 112b. A frontsheet 130 may be disposed on the core 100 layers.

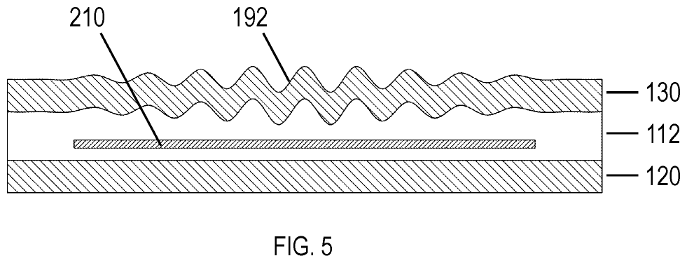

In a second step, shown in FIG. 3C, the flexible solar panel is laminated as a flat sheet. The frontsheet 130 may be textured during the lamination process by a plurality of techniques known in the art, such as, for example, textured rollers in a roll-to-roll lamination process, a textured mold in a flat lamination process, or a textured insert placed on the frontsheet in a flat lamination process. As depicted in FIG. 5, the texture 192 is imparted to the thin frontsheet 130 by one of the above-mentioned techniques and is accommodated by the flowable polymer encapsulant 112. In this way, the solar cells 210 are not stressed by the texturing process.

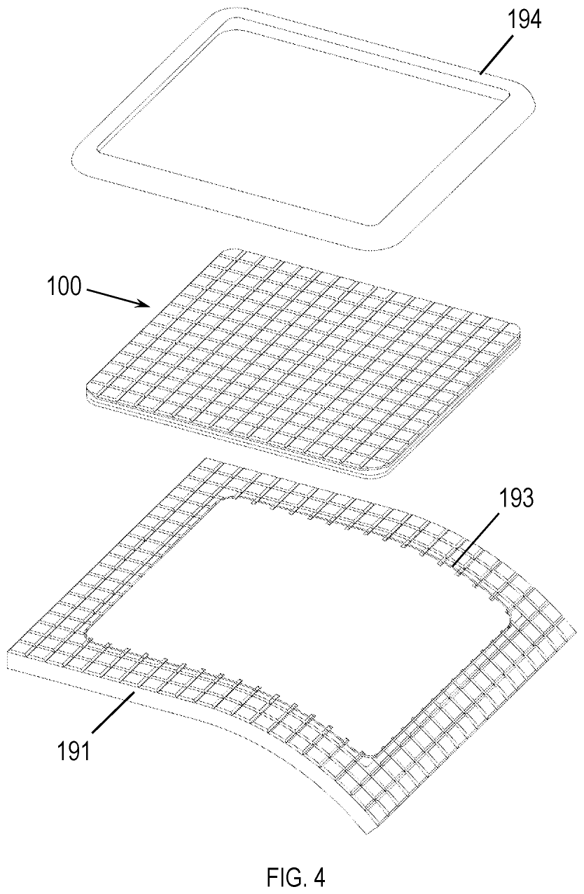

In a third step, the solar module 100 may be trimmed to fit the appropriate space, such as the untextured portion, on the surface of the dashboard panel 191, as shown in the assembly of FIG. 4. Trimming may be achieved through mechanical cutting or laser cutting. In a fourth step, an adhesive 195, such as adhesive transfer tape or spray on adhesive, may be applied to the bottom of the flex panel 100. Alternatively, steps 3 and 4 may be reversed, that is, the adhesive (and its protective layer, if present) may be applied prior to trimming. In a fifth step, illustrated in FIG. 4, the flexible solar module 100 is adhered to the dashboard panel 191 of the molded dash panel 191. In a sixth step, also shown in FIG. 4, the border 194 is fitted into the groove 193 on the dashboard panel 191, thereby securing the edge of the solar module 100.

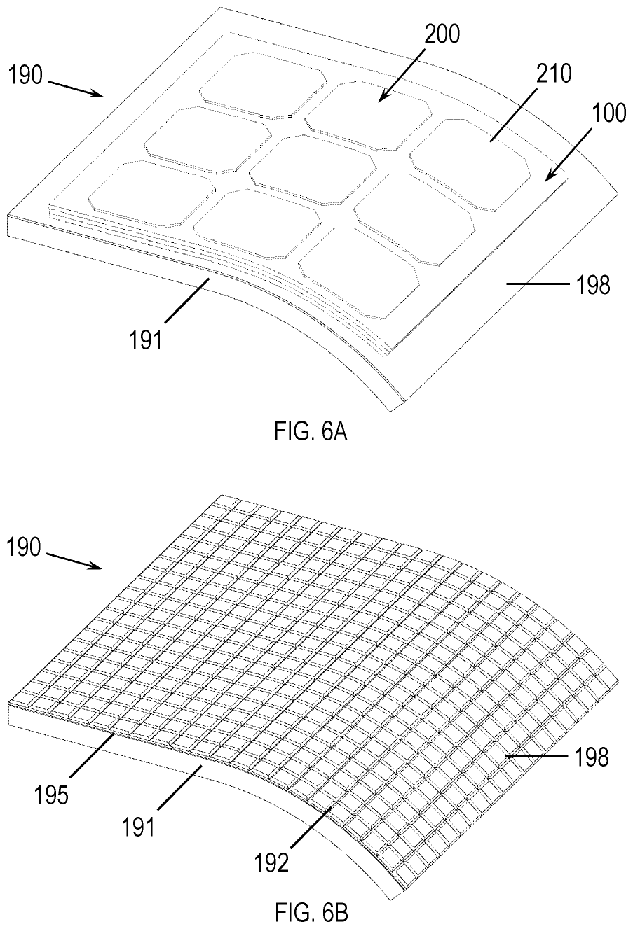

Referring to FIGS. 6A and B, according to another embodiment, a flexible solar module 100 having one axis of curvature can be integrated with a dashboard assembly 190. The dashboard assembly 190 comprises a flexible solar module 100 disposed in a recess within a molded panel 191 and covered by a cap layer 198. In FIG. 6A, the cap layer 196 is shown without texture for clarity. The solar module 100 comprises a solar cell array 200 further comprised of individual solar cells 210 and interconnects (not shown). The recess in which the solar module 100 is disposed has a depth that is substantially the same as the thickness of the solar module 100. The dashboard panel 191 may have simple or complex curvature. The recess may be flat or have simple curvature, that is, curved in one direction. The dashboard assembly 190 further comprises a textured 192, optically clear cap layer 198 disposed on the top surface of the panel 191, as shown in FIG. 6B.

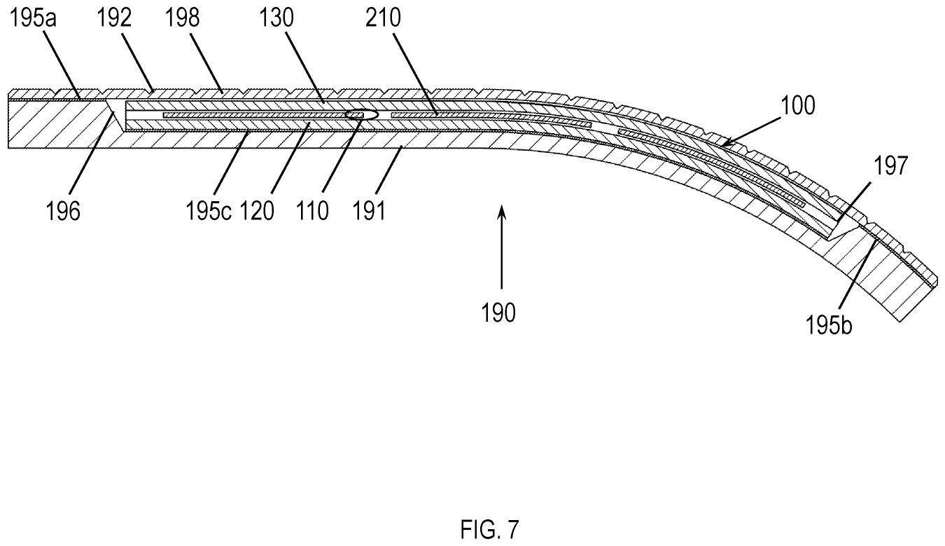

Referring to FIG. 7, the dashboard assembly 190 comprises a molded panel 191 with a recess 196 disposed in a top surface. The flexible solar module 100 disposed therein comprises a core 110, a backsheet 120 and a frontsheet 130, as previously described. The solar cells 210 within the core 110 may be flat or curved in one direction. Similarly, the thicknesses of the layers can be selected such that the panel 100 remains flexible after lamination. The frontsheet 130 may be textured to reduce reflectivity, or it may remain smooth. The recess 196 comprises side walls having a draft and/or chamfer forming a gap 197 between the solar module 100 and the wall of the recess 196. The gap 197 may be left open or filled with adhesive or other sealant. The textured 192 cap layer 198 is disposed over the surfaces of both the molded panel 191 and solar module 100 which are substantially flush, resulting in a contiguous, textured surface.

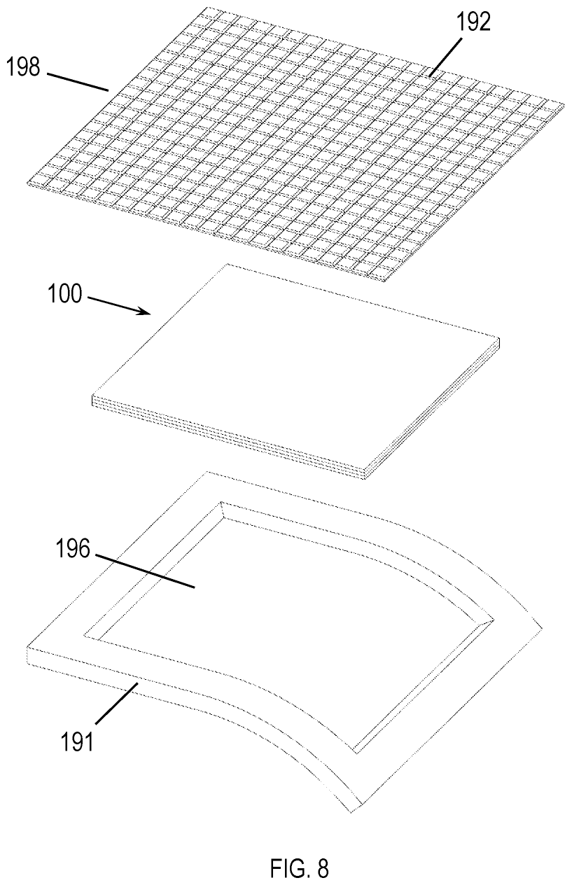

As illustrated in FIGS. 3A, 3B and 8, a method of manufacturing a dashboard assembly 190 with a flexible solar module 100 also is provided. In a first step, shown schematically in FIG. 3A, the solar panel layers are arranged in a stack. This layered stack represents the order of the layers and may be implemented as sheets, as in a flat lamination process, or as rolls, as in a roll-to-roll lamination process. The backsheet 120 is disposed at the bottom, followed by the core 110 comprising a bottom encapsulant 112a, the solar cells 210, and a top encapsulant 112b. A frontsheet 130 may be disposed on the core 100 layers. In a second step, shown in FIG. 3B, the flexible solar panel 100 is laminated as a flat sheet. In a third step, the flexible solar module 100 may be trimmed to fit the recess 196 on the dashboard panel. Trimming may be achieved through mechanical cutting or laser cutting. In a fourth step, an adhesive 195, such as adhesive transfer tape or spray on adhesive, may be applied to the bottom of the flexible solar module 100. Alternatively, steps 3 and 4 may be reversed, that is, the adhesive (and its protective layer, if present) may be applied prior to trimming. In a fifth step, illustrated in FIG. 8, the flexible solar module 100 is adhered within the recess 196 of the molded dash panel 191. In a sixth step, also shown in FIG. 8, a textured 192, optically transparent cap layer 198 is applied over the surface of the dashboard 191 and flexible solar module 100, thereby encasing the flexible solar module 100 and providing a level, consistent finish to the dashboard assembly 190.

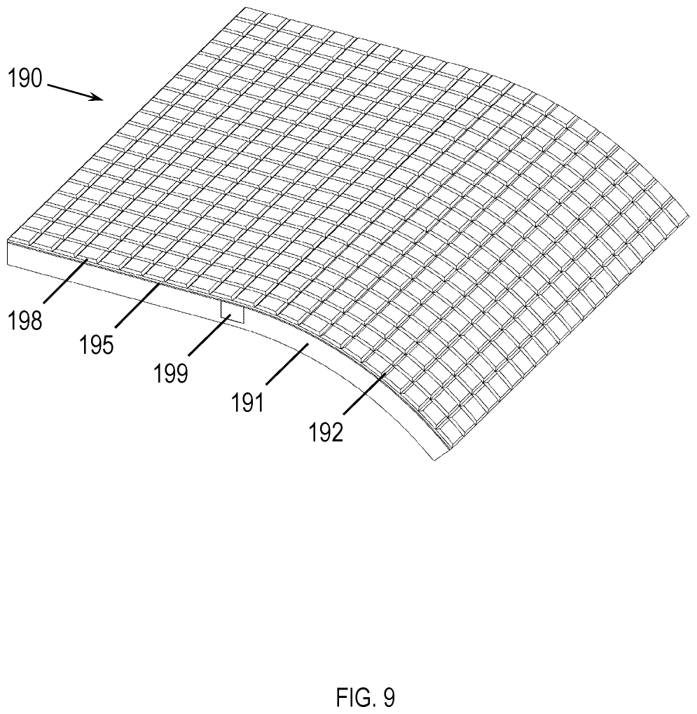

In yet another embodiment, the cap layer 198 may be an optically clear, molded component that fastens to the dash panel 191 with snap features and/or fasteners, as shown in FIG. 9. The dashboard assembly 190 comprises a flexible solar module 100 (not shown) disposed in a recess 196 within a molded panel 191 and covered by a cap layer 198. The recess 196 has a dimension that is substantially the same as the thickness of the solar module such that the solar module is disposed to the depth of the recess 196. The dashboard panel 191 may have simple or complex curvature. The recess may be flat or have simple curvature, that is, curved in one direction. Snap assembly features may be disposed on the cap layer 198 and other dash molded components. Alternatively, the cap layer 198 may be secured via an adhesive, such as silicone, or by the use of fasteners, such as plastic rivets commonly used in the automotive industry.

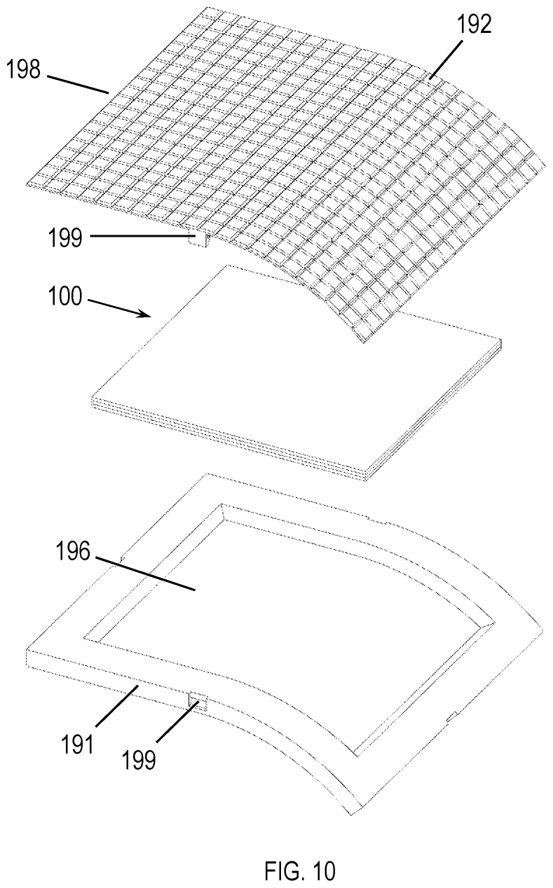

FIGS. 3A, 3B and 10, illustrate a method of manufacturing a dashboard assembly 190 having flexible solar module 100 and a cap layer 198. In a first step, shown schematically in FIG. 3A, the solar panel layers are arranged in a stack. The stack represents the order of the layers and may be implemented as sheets, as in a flat lamination process, or as rolls, as in a roll-to-roll lamination process. The backsheet 120 is disposed at the bottom, followed by the core 110 comprising a bottom encapsulant 112a, the solar cells 210, and a top encapsulant 112b. A frontsheet 130 may be disposed on the core 100 layers. In a second step, shown in FIG. 3B, the flexible solar panel is laminated as a flat sheet. In a third step, the solar panel may be trimmed to fit the recess 196 on the dashboard panel. Trimming may be achieved through mechanical cutting or laser cutting. In a fourth step, an adhesive 195, such as adhesive transfer tape or spray on adhesive, may be applied to the bottom of the flex panel 100. Alternatively, steps 3 and 4 may be reversed, that is, the adhesive (and its protective layer, if present) may be applied prior to trimming. In a fifth step, illustrated in FIG. 10, the flexible solar module 100 is adhered within the recess 196 of the molded dash panel 191. In a sixth step, also shown in FIG. 10, a textured 192, optically transparent cap layer 198 is fastened to the dashboard 191 by means of snap features 199 thereby covering the solar panel 100 and providing a durable, aesthetic finish to the dashboard assembly 190.

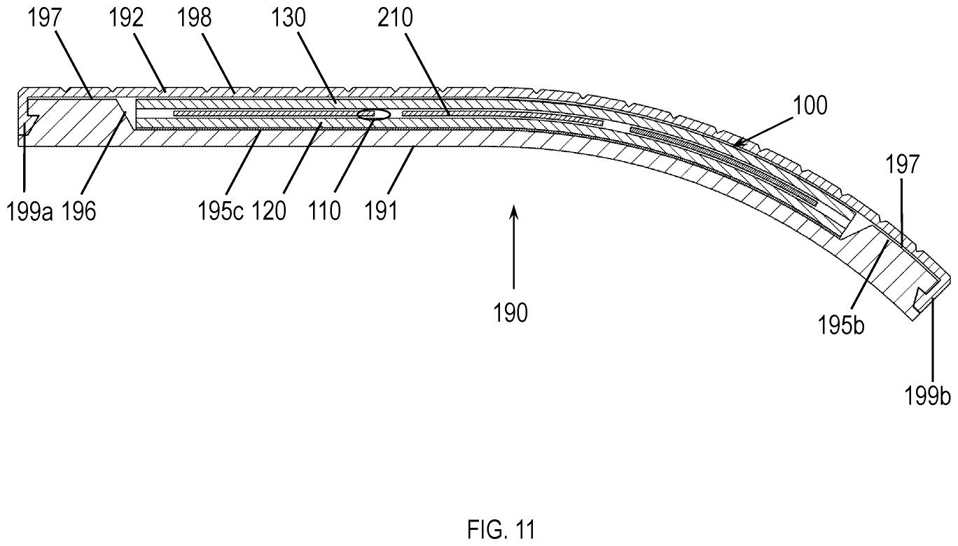

Referring to FIG. 11, the dashboard assembly 190 comprises a molded panel 191 with a recess 196 disposed in a top surface. The flexible solar module 100 disposed therein comprises a core 110, a backsheet 120 and a frontsheet 130, as previously described. The solar cells 210 within the core 110 may be flat or curved in one direction. The thicknesses of the layers are chosen such that the panel 100 remains flexible after lamination, as before. However, in this embodiment the frontsheet 130 is not textured. The recess 196, more clearly visible in the section view, may have drafted (chamfered) side walls. The textured 192 molded cap 198 is disposed over the surfaces of both the molded panel 191 and solar module 100, which are substantially flush, and secured by latching features 199a, b. As a result, there may be a gap 197c between the solar module 100 and the wall of the recess 196. Additionally, a small gap can exist between the top surfaces of the dashboard panel 191 and solar module 100 and the bottom surface of the cap 198. This gap 197a, 197b may be filled with adhesive, or a sealant, such as silicone, or simply left open. According to this embodiment of the dashboard assembly 190, certain advantages to filling the gap include a reduction of reflection from the cap layer 198 and increase light transmission to the solar cells 210.

Applications of the aforementioned embodiments are not necessarily limited to vehicle or dashboard applications. For example, one or more of the embodiments may be directed to the rear window subpanel of a vehicle. Other exemplary applications include, but are not limited to, architectural panels exposed to light for interior use, vehicle panels, marine panels, aeronautical, spacecraft, and other panel applications

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

1. A panel assembly including a solar module, said panel assembly comprising:
a molded panel curved in one or more directions; and
a flexible solar module integrated with said molded panel, said flexible solar module including:
a backsheet,
a core coupled to said backsheet, said core including one or more solar cells curved in said one or more directions and an encapsulant, said encapsulant adapted to encapsulate said one or more cells, and
a frontsheet coupled to said core.

2. The panel assembly including a solar module according to claim 1, wherein said molded panel is configured for a dashboard for installation in a vehicle.

3. The panel assembly including a solar module according to claim 1, wherein said molded panel includes an upper surface.

4. The panel assembly including a solar module of claim 3, wherein said flexible solar module is integrated with said molded panel by an adhesive layer disposed between said upper surface and said backsheet.

5. The panel assembly including a solar module according to claim 4, wherein:
said flexible solar module further comprises a perimeter, said perimeter defined by the edges of said backsheet, said core, and said frontsheet forming said flexible solar module,
said upper surface of said molded panel comprises a channel formed proximate said perimeter and formed in said molded panel, and
a gasket coupled to and surrounding said perimeter, said gasket comprising a complementary portion adapted to couple to said upper surface of said molded panel about said channel, so that said gasket forms a seal about said perimeter extending from said frontsheet to said upper surface.

6. The panel assembly including a solar module according to claim 1, wherein said molded panel further comprises an upper surface and a recess disposed inwardly from said upper surface.

7. The panel assembly including a solar module according to claim 6, wherein said flexible solar module is integrated with said molded panel by an adhesive layer disposed between said recess and said backsheet, and wherein said frontsheet of said flexible solar module is disposed substantially flush with said upper surface of said molded panel.

8. The panel assembly including a solar module according to claim 7 further comprising an optically clear cap layer coupled to said upper surface and extending over said recess, and so that said optically clear cap layer uniformly extends over said dashboard.

9. The panel assembly including a solar module according to claim 8, wherein said optically clear cap layer is adhesively coupled to said upper surface and said frontsheet.

10. The panel assembly including a solar module according to claim 8, wherein said optically clear cap layer comprises an optically clear molded cap panel coupled to said molded panel.

11. The panel assembly including a solar module according to claim 10, wherein said coupling wherein said coupling of said optically clear molded cap panel to said molded panel comprises one or more coupling methods selected from the group consisting of adhesives, sealants, snap fit features, rivets, and threaded fasteners.

12. A panel assembly including a solar module, said panel assembly comprising:
a molded panel including an upper surface; and
a flexible solar module integrated with said molded panel, said flexible solar module including:
a backsheet,
a core coupled to said backsheet, said core including one or more solar cells and an encapsulant, said encapsulant adapted to encapsulate said one or more cells, and
a frontsheet coupled to said core;
wherein said flexible solar module further comprises a perimeter, said perimeter defined by the edges of said backsheet, said core, and said frontsheet forming said flexible solar module
wherein said upper surface of said molded panel comprises a channel formed proximate said perimeter and formed in said molded panel,
and wherein at least one of said frontsheet of said flexible solar module and the portion of said upper surface surrounding said channel is textured.

13. The panel assembly including a solar module according to claim 12, wherein said molded panel is configured for a dashboard for installation in a vehicle.

14. The panel assembly including a solar module of claim 12, wherein said flexible solar module is integrated with said molded panel by an adhesive layer disposed between said upper surface and said backsheet.

15. The panel assembly including a solar module according to claim 14, wherein a gasket is coupled to and surrounds said perimeter, said gasket comprising a complementary portion adapted to couple to said upper surface of said molded panel about said channel, so that said gasket forms a seal about said perimeter extending from said frontsheet to said upper surface.

16. A panel assembly including a solar module, said panel assembly comprising:
a molded panel including an upper surface and a recess disposed inwardly from said upper surface;
a flexible solar module integrated with said molded panel along at least a portion of said recess, said flexible solar module including:
a backsheet,
a core coupled to said backsheet, said core including one or more solar cells and an encapsulant, said encapsulant adapted to encapsulate said one or more cells, and
a frontsheet coupled to said core;
wherein said frontsheet of said flexible solar module is disposed substantially flush with said upper surface of said molded panel; and
an optically clear cap layer is coupled to said upper surface and extends over said recess so that said optically clear cap layer uniformly extends over said molded panel,
wherein at least a portion of said optically clear cap layer is textured.

17. The panel assembly including a solar module according to claim 16, wherein said molded panel is configured for a dashboard for installation in a vehicle.

18. The panel assembly including a solar module according to claim 16, wherein said flexible solar module is integrated with said molded panel by an adhesive layer disposed between said recess and said backsheet.

19. The panel assembly including a solar module according to claim 16, wherein said optically clear cap layer is adhesively coupled to said upper surface and said frontsheet.

20. The panel assembly including a solar according to claim 16, wherein said optically clear cap layer comprises an optically clear molded cap panel coupled to said molded panel.

21. The panel assembly including a solar module according to claim 20, wherein said coupling of said optically clear molded cap panel to said molded panel comprises one or more coupling methods selected from the group consisting of adhesives, sealants, snap fit features, rivets, and threaded fasteners.

22. A panel assembly including a solar module, said panel assembly comprising:
a molded panel; and
a flexible solar module integrated with said molded panel, said flexible solar module including:
a backsheet,
a core coupled to said backsheet, said core including one or more solar cells and an encapsulant, said encapsulant adapted to encapsulate said one or more cells, and
a frontsheet coupled to said core;
wherein a colored appearance is formed on at least a portion of one or more of said molded panel, said backsheet, and said frontsheet.

23. The panel assembly including a solar module according to claim 22, wherein said molded panel is configured for a dashboard for installation in a vehicle.

24. The panel assembly including a solar module according to claim 22, wherein said molded panel includes an upper surface.

25. The panel assembly including a solar module of claim 24, wherein said flexible solar module is integrated with said molded panel by an adhesive layer disposed between said upper surface and said backsheet.

26. The panel assembly including a solar module according to claim 25, wherein:
said flexible solar module further comprises a perimeter, said perimeter defined by the edges of said backsheet, said core, and said frontsheet forming said flexible solar module,
said upper surface of said molded panel comprises a channel formed proximate said perimeter and formed in said molded panel, and
a gasket coupled to and surrounding said perimeter, said gasket comprising a complementary portion adapted to couple to said upper surface of said molded panel about said channel, so that said gasket forms a seal about said perimeter extending from said frontsheet to said upper surface.

27. The panel assembly including a solar module according to claim 22, wherein said molded panel further comprises an upper surface and a recess disposed inwardly from said upper surface.

28. The panel assembly including a solar module according to claim 27, wherein said frontsheet of said flexible solar module is disposed substantially flush with said upper surface of said molded panel, and wherein said flexible solar module is integrated with said molded panel by an adhesive layer disposed between said recess and said backsheet.

29. The panel assembly including a solar module according to claim 28 further comprising an optically clear cap layer coupled to said upper surface and extending over said recess, and so that said optically clear cap layer uniformly extends over said dashboard.

30. The panel assembly including a solar module according to claim 29, wherein said optically clear cap layer comprises an optically clear molded cap panel coupled to said molded panel.

31. The panel assembly including a solar module according to claim 30, wherein said coupling of said optically clear molded cap to said molded panel comprises one or more coupling methods selected from the group consisting of adhesives, sealants, snap fit features, rivets, and threaded fasteners.
